(19) United States
(12) Patent Application Publication
(10) Pub. No.: US 2025/0343126 A1
(43) Pub. Date: Nov. 6, 2025

(54) Electronic Component Package

(71) Applicant: Nippon Telegraph and Telephone Corporation, Tokyo (JP)

(72) Inventors: Ken Tsuzuki, Musashino-shi, Tokyo (JP); Kiyofumi Kikuchi, Musashino-shi, Tokyo (JP); Makoto Jizodo (deceased), Musashino-shi, Tokyo (JP)

(21) Appl. No.: 18/871,214

(22) PCT Filed: Jun. 15, 2022
(86) PCT No.: PCT/JP2022/024031

§ 371 Date: Dec. 3, 2024

(51) Int. Cl. H01L 23/498

(52) U.S. Cl. CPC H01L 23/49838

(57) ABSTRACT

An electronic component package in which pads are disposed on an x-y plane in a lattice pattern in an x-direction and a y-direction orthogonal to the x-direction at a predetermined pitch, in which a suppression width of a solder resist or a ceramic coat and a size of a pad of a signal electrode pad disposed on the outermost periphery and configured to input or output a high-frequency signal, and a ground electrode pad adjacent to the signal electrode pad in the x-direction and the y-direction are formed to be smaller than a suppression width of the solder resist or the ceramic coat of other pads and a size of a pad.

### TECHNICAL FIELD

The present invention relates to an electronic component package such as an optical transceiver used in an optical communication system.

### BACKGROUND ART

In recent years, in a data center and the optical communication industry, a small-sized optical transceiver capable of increasing a transmission rate per volume has been put into practical use. For example, a size of a form factor of a datacom and telecom transceiver called QSFP-DD is approximately 18.35 mm×58.26 mm×8.5 mm. In order to mount a transceiver for high-speed optical communication on such a small-sized form factor, a high-frequency module equipped with ball grid arrays (BGA) and land grid arrays (LGA), which can be mounted by solder reflow on printed circuit boards (PCB), are now being used not only in ICs but also in optical transceivers. Both the BGA and the LGA are used in an electronic component package using a surface mounting technique (SMT) for electrically connecting to a printed wiring board via solder bumps. One with hemispherical solder on circular electrode pads disposed in a lattice pattern on a bottom surface of the package is called a ball grid array (BGA), and one without solder is called a land grid array (LGA). Since the LGA is not mounted with solder, when reflow mounting is performed on the printed wiring board, electrical connections are performed by applying hard solder or by supplying spherical solder balls. Although there are various other names based on fine classification in the surface mounting technique for performing electrical connection via solder bumps, BGA, LGA, etc. are simply referred to as BGA in this specification.

As the terminal of the optical transceiver, there are a ground terminal, a DC terminal for supplying power, an analogue or digital control terminal, and a signal terminal for inputting and outputting high-speed electric signals. The number of DC terminals varies depending on the module. On the other hand, the number of terminals for signal electrodes for inputting or outputting the signal is usually a total of 8 differential signal pairs, 4 pairs for transmission and 4 pairs of reception signals, if it is an optical transceiver for coherent optical communication. Since the terminals for signal electrodes of the optical transceiver input and output signals to and from the digital signal processing processor disposed adjacent or a device (host device) forming the optical communication system, they are generally gathered at one end of the package of the optical transceiver in many cases.

In order to reduce the size, while providing all the terminals necessary for the operation of these optical transceivers, it is necessary to densely dispose the pitches of the pads of the BGA used for the optical transceiver. In addition, in order to equalize the mounting stress of the BGA, pads of the BGA are disposed at equal intervals in the x-y direction in the plane of the BGA, and the sizes of the pads of the respective BGAs are often the same.

FIG. 1 is a diagram showing an electronic component package having equally spaced BGA pads which is the related art. As shown in FIG. 1, one surface 12 of the electronic component package 10 is formed of a resin such as glass epoxy or a ceramic, and on the one surface (x-y surface), circular BGA pads 14 are disposed in a lattice pattern at regular intervals in the x-y direction at a predetermined pitch. Each BGA pad 14 is formed of a metal such as aluminum or copper, and can be soldered by plating gold, silver or palladium.

FIG. 2 shows two adjacent BGA pads 14a and 14b of the electronic component package of FIG. 1. FIG. 2(a) is a top view of the BGA pad, and FIG. 2(b) is a cross-sectional view of the BGA pad. The BGA pads 14a and 14b are formed of a conductive metal such as aluminum or copper, on one surface 12 of an electronic component package formed of a resin such as glass epoxy or ceramic. Each BGA pad is plated with gold, silver, and palladium so that it can be soldered. The BGA pad shown in FIG. 2 is circular and its diameter is indicated by B. A pitch between two adjacent BGA pads 14a and 14b is indicated by C. In this specification, the pitch of the BGA pads means the center interval as shown in FIG. 2.

In the BGA pads 14a and 14b, in order to prevent the BGA pads 14a and 14b from being peeled off by stress applied to the electronic component when the electronic component package is mounted by solder or when the electronic component is used, if the electronic component package is made of resin, a solder resist is disposed, and if it is made of ceramic, a ceramic coat is disposed to be caught by the edges of the BGA pads 14a and 14b, as shown in FIG. 2(b). In FIG. 2(a), only a portion (22) that overlaps the BGA pads 14a and 14b in the solder resist or the ceramic coat 20 shown in FIG. 2(b) is shown. The solder resist or the ceramic coat defines pad openings 24a and 24b which are areas occupied by the solder bumps in the BGA pad, and the diameters of the pad openings 24a and 24b are indicated by A in FIG. 2. FIG. 2 shows a distance D between adjacent BGA pads and a gap G between the BGA pads. Although not shown in the diagram, wiring from each pad of the BGA is done through inner layer wiring called vias, which is formed inside the substrate that makes up one surface of the package made of resin or ceramics.

The pad opening diameter A, the BGA pad diameter B, and the pitch C of the BGA pads are preferably large from the viewpoint of easiness of mounting an electronic component package having the BGA pads on the printed wiring board or the like. However, in order to increase the density of the pads from the viewpoint of miniaturization of the device, these are desirably small. The degree of reduction in size is limited by restrictions such as difficulty in mounting electronic components on the printed wiring board, difficulty in forming electrodes, and the diameter of vias in the inner layer wiring. Since the pad opening is required to be disposed without protruding from the BGA pad, the suppression width of the solder resist or the ceramic coat (the widths of 22a and 22b of FIG. 2(a)) (B−A)/2 is required to be approximately 40 to 100 μm to ensure the strength of the BGA pad.

FIG. 3 is a table that shows a relationship between the pad pitch of BGA and LGA and the pad opening diameter, which is extracted from the “JEITA EDR-7316C, Integrated Circuit Package Design Guide”, which is a guideline provided by the Japan Electronics and Information Technology Industries Association (JEITA). A value indicated by e is the pad pitch C, and values indicated by min., nom., max., are the minimum, standard, and maximum values of the pad opening diameter A, respectively. The unit is (mm). In the international standard size, the pad opening diameter allowed for the pad pitch is a certain value having a width indicated by the minimum value and the maximum value. The solder formed on the BGA pad connects the printed wiring board or the like and the electronic component, and at the same time, absorbs fluctuation of the interval between the joint surfaces due to warpage of both. Although the height of the solder required differs depending on the amount of warpage to be absorbed, the height of the solder after mounting on the printed wiring board or the like (the distance between the printed wiring board or the like and the pad of the BGA) is about half the diameter A of the pad opening. In the FBGA and FLGA of FIG. 3, F denotes a fine pitch. In the C-FLGA and P-FLGA, C-represents that the substrate material is ceramic, and P-means that the substrate material is plastic, that is, the resin is a resin such as glass epoxy.

The wiring from the BGA pad is performed by an inner layer wiring called a via formed inside a substrate forming one surface of an electronic component package made of resin or ceramics as shown in FIG. 4(b). When a transmission path for propagating a high-frequency signal is formed by using an inner layer wiring such as a via formed in the laminated substrate as shown in FIG. 4(b), it is necessary to adjust the characteristic impedance of the inner layer wiring. The characteristic impedance is a characteristic impedance (a ratio of a voltage and a current generated in a propagation medium) of a transmission path, and in an electronic component, the resistance is usually set to 50Ω for single-phase transmission and 100Ω for differential transmission. In order to set the characteristic impedance of the inner-layer wiring using the via to 50Ω, it is most effective to dispose the via forming the signal electrode for propagating the high-frequency signal and the via forming the ground electrode for flowing the return current concentrically like a coaxial line.

FIG. 4 is a diagram showing the structure of an electronic component package formed of resin or ceramic, which includes an inner layer wiring for propagating a high-frequency signal passing through the inside of a substrate forming one surface of the package from the pad of BGA. FIG. 4(a) is a diagram showing one surface 12 of the package, and FIG. 4(b) is a diagram showing a cross-sectional structure of a substrate forming one surface of the package. As shown in FIG. 4(b), the substrate is a laminated substrate including a plurality of layers 121 to 125. Lands 42 for receiving the vias 40 are formed on the surfaces of the respective layers of the laminated substrate, and vias 40 penetrating the layers are formed in the respective layers. As is apparent from the drawing, an electrode serving as a propagation path from the surface of the substrate to penetrate between layers is wired by the via 40 and the land 42.

FIG. 4(a) shows vias 40a and lands 42a forming signal electrodes for transmitting high-frequency signals, and vias 46a to 46h forming ground electrodes disposed concentrically around them. In FIG. 4(a), vias 40a to 40d and lands 42a to 42d forming four signal electrodes and four sets of ground electrodes disposed concentrically around them are shown. However, for convenience of explanation, only the vias 46a to 46h forming one set of four sets of ground electrodes are denoted by reference numerals. The ground electrode is made up of a plurality of vias 46a to 46h disposed concentrically around the signal electrode, and a connected land pattern 48 concentrically surrounding the vias 40a and lands 42a forming the signal electrode. The relative dielectric constant of the material of the electronic component package 12 is about 3 in the case of resin, and about 5 to 10 in the case of ceramics. The lower the dielectric constant, the less loss there can be in the transmission path. A gap between the pads required to set the characteristic impedance of the coaxial transmission path constructed in this way to 50Ω is as follows. In the case of a resin substrate, the gap between the land 42 of the signal electrode and the plurality of vias 46a to 46h or land pattern 48 around it is approximately 1.5 times the diameter (pad diameter) of the via or land of the signal electrode, and in the case of ceramic substrates, the gap is about 2.5 to 6.5 times.

The increase in communication capacity requires an increase in signal speed. In order to increase the communication speed, the speed of signal exchange between the IC and the optical transceiver is increasing year by year. At present, a device having a baud rate of 32 Gbaud to 64 Gbaud has been put into practical use, but it has been studied to increase the speed up to 96 Gbaud and 128 Gbaud in the future. In the high frequency range, the operating frequency required for communication devices is generally about 0.7 times the baud rate, and the operating frequency is 45 GHz for 64 Gbaud, 70 GHz for 96 Gbaud, and about 90 GHz for 128 Gbaud. In this way, the communication device is required to operate in a wide frequency range from several hundred kHz in a low speed range to about 90 GHz in a high speed range.

When electronic equipment such as an optical transceiver having a BGA pad is miniaturized and the signal speed is increased, it is necessary to reduce the pitch of the BGA pad and to appropriately set the interval between the signal electrode and the ground electrode.

In the propagation of the high-frequency signal, when the length of a part where the characteristic impedance is not matched is suppressed to 1/20 or less of the wavelength, the mismatching of the characteristic impedance can be allowed without any problem. For example, the wavelength of a 45 GHz high-frequency signal is 6.7 mm in a vacuum. Since the refractive index of the resin or ceramic material is about 2 to 3 on the wiring of a board made of resin or ceramic materials, the wavelength is about 3.3 mm to 2.2 mm. Then, when propagating a high-frequency signal of 45 GHz through wiring on a board made of resin or ceramic material, the allowable length of the portion in which impedance is not matched is 0.11 mm to 0.16 mm. Since this length is smaller than the size of the BGA pad, mismatching of characteristic impedance at the BGA connection part cannot be ignored in propagation of a high-frequency signal. Therefore, it is necessary to design the BGA pad used for an electronic component package used for the purpose of propagating a high-frequency signal so that the characteristic impedance can be matched.

In order to miniaturize electronic components and optical transceivers used in an optical communication system while having all terminals necessary for their operation, BGA pads need to be densely disposed. The pitch C of BGA pads of 0.5 mm interval to 0.4 mm interval, 0.3 mm interval, etc., is starting to be used, and the gap between BGA pads is tending to become narrower. As described above, the BGA pad requires a certain size to facilitate solder mounting. Therefore, the diameter of the BGA pad formed on the surface of the substrate is made larger than the diameter of the land used in the inner layer of the substrate. For this reason, it is difficult to secure a size required for setting the characteristic impedance to 50Ω, for the gap between the PGA pad forming the signal electrode and the BGA pad forming the ground electrode positioned around the signal electrode, with respect to the diameter of the BGA pad forming the signal electrode. As described above, solder resist is disposed on the BGA pad in the case of resin, and a ceramic coat is disposed on the end of the pad in the case of ceramic.

FIG. 5 shows the suppression width of the solder resist or ceramic coating of the typical BGA pad shown in FIG. 1. As described above, the circular BGA pads 14 are disposed at regular intervals in the x-y direction at a predetermined pitch in the lattice pattern in the x-y direction within the x-y plane which is one surface of the electronic component package. As shown in FIG. 2, in the BGA pad 14, a portion 22 in which the solder resist or the ceramic coat 20 overlaps the pad exists around the pad opening 24 for solder connection. The solder resist or the ceramic coat 20 defines the size of the solder opening 24 which is an area occupied by the solder bump in the pad.

As described above, it is necessary to form the portion 22 around the BGA pad 14 which overlaps with the solder resist or the ceramic coat 20. Therefore, the diameter B of the BGA pad needs to be larger than the diameter A of the pad opening 24. Further, as described above, the suppression width of the solder resist or the ceramic coat is required to be about 40 to 100 μm. In order to secure this suppression width, the pad diameter B needs to be larger than the required pad opening diameter A by the suppression width 22. As a result, the gap D between the BGA pad forming the signal electrode and the BGA pad forming the ground electrode becomes narrower by the suppression width 22 than in a case where the size of the required solder bump area (opening diameter A) is secured. Therefore, there is a problem that the characteristic impedance of the transmission path constituted by the signal electrode and the ground electrode is further reduced.

### CITATION LIST

### Patent Literature

[PTL 1] WO 2021/075035

### SUMMARY OF INVENTION

An object of the present invention is to provide an electronic component package having pads, such as ICs and optical transceivers having pads, which can prevent deterioration in characteristic impedance of a transmission path of a high-frequency signal by appropriately setting a gap between a signal electrode pad and a ground electrode pad even when the pads are densely disposed. Further, an object of the present invention is to provide an electronic component for an IC and an optical transceiver having higher speed and high performance and to provide an optical communication system having small size, large capacity and high-function, by preventing the impedance of the transmission path for transmitting high-frequency signals from becoming low even when the BGA pads of an electronic component package are densely disposed, without increasing the size of electronic components.

In order to achieve such an object, the present invention has the following configuration.

### Configuration 1

An electronic component package in which pads are disposed on an x-y plane in a lattice pattern in an x-direction and a y-direction orthogonal to the x-direction at a predetermined pitch, in which a suppression width of a solder resist or a ceramic coat and a size of a pad of a signal electrode pad disposed on one side of the outermost periphery and configured to input or output a high-frequency signal, and a ground electrode pad adjacent to the signal electrode pad in the x-direction and the y-direction are smaller than a suppression width of the solder resist or the ceramic coat of other pads and a size of a pad.

### Configuration 2

An electronic component package in which pads are disposed on an x-y plane in a lattice pattern in an x-direction and a y-direction orthogonal to the x-direction at a predetermined pitch, in which a suppression width of a solder resist or a ceramic coat and a size of a pad of a signal electrode pad disposed in a second row on one side of the outermost periphery and configured to input or output a high-frequency signal, and a ground electrode pad adjacent to the signal electrode pad in a x-direction and a y-direction are smaller than a suppression width of the solder resist or the ceramic coat of other pads and a size of a pad.

### Configuration 3

An electronic equipment package in which pads are disposed at a predetermined pitch in a lattice pattern in an x-direction of an x-y plane and a y-direction orthogonal to the x-direction, the electronic component package comprising:
a signal electrode pad disposed on one side of an outer periphery of an electronic component and configured to input or output a high-frequency signal; and a ground electrode pad neighboring to the signal electrode pad in the x-direction,
in which the pad adjacent to the signal electrode pad in the x-direction is deleted, and an interval between the signal electrode pad and the ground electrode pad neighboring to the signal electrode pad in the x-direction is larger than an interval between other pads.

According to the electronic component package such as an IC and an optical transceiver of the above-mentioned constitution 1 to 3, since the characteristic impedance of the pad connection part is not lowered and impedance matching is attained, it is possible to provide an optical communication system of small size, high capacity, and high performance.

### BRIEF DESCRIPTION OF DRAWINGS

FIG. 1 is a diagram showing an electronic component package having equally spaced BGA pads of which a related art.

FIG. 2 is a diagram showing two adjacent BGA pads of the electronic component package of FIG. 1.

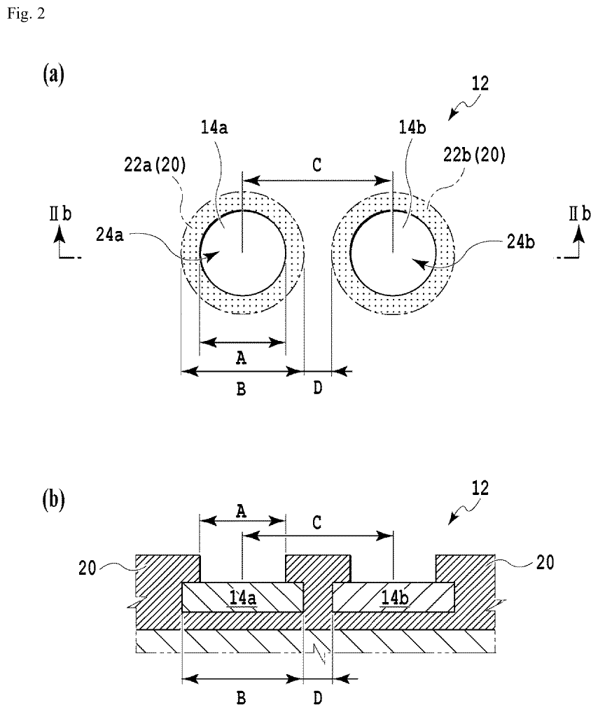

FIG. 3 is a table showing a relationship between pad pitches of BGA and LGA and a pad opening diameter, extracted from JEITA EDR-7316C, Integrated Circuit Package Design Guide.

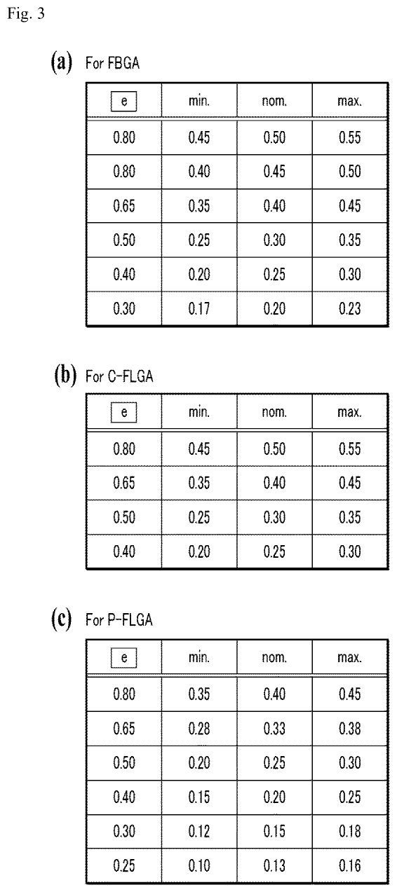

FIG. 4 is a diagram showing a structure of a substrate formed of resin or ceramic and equipped with an inner layer wiring that propagates high-frequency signals that pass from the pads of the BGA through the inside of the substrate that constitutes one surface of the package.

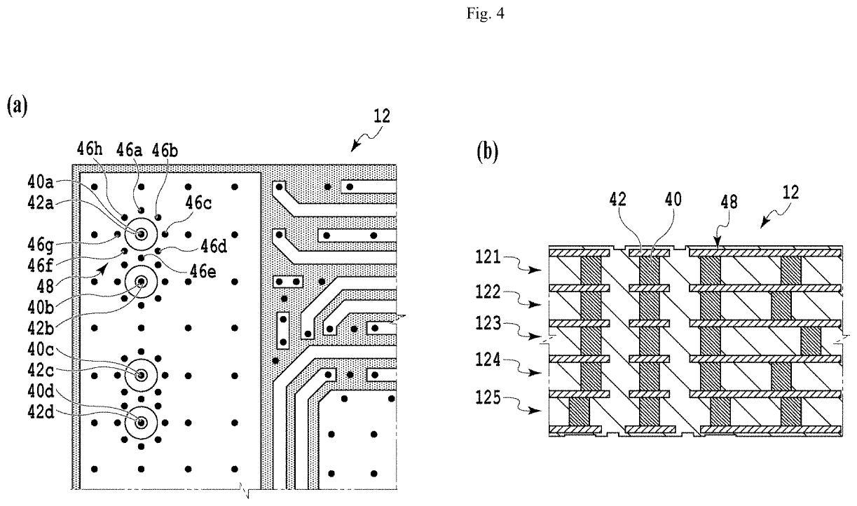

FIG. 5 is a diagram showing a BGA pad with a solder resist of a general BGA or a ceramic coat seen through.

FIG. 6 is a diagram showing an electronic component package having a BGA pad according to Example 1 of the present invention.

FIG. 7 is a diagram showing an electronic component package having a BGA pad according to Example 2 of the present invention.

FIG. 8 is a diagram showing an electronic component package having a BGA pad according to Example 3 of the present invention.

FIG. 9 is a diagram showing an electronic component package having a BGA pad according to Example 4 of the present invention.

### DESCRIPTION OF EMBODIMENTS

Embodiments of the present invention will be described in detail below with reference to the drawings.

### Example 1

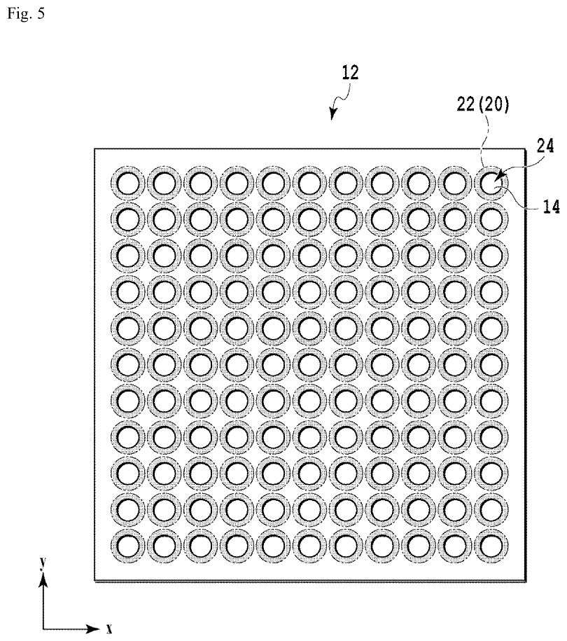

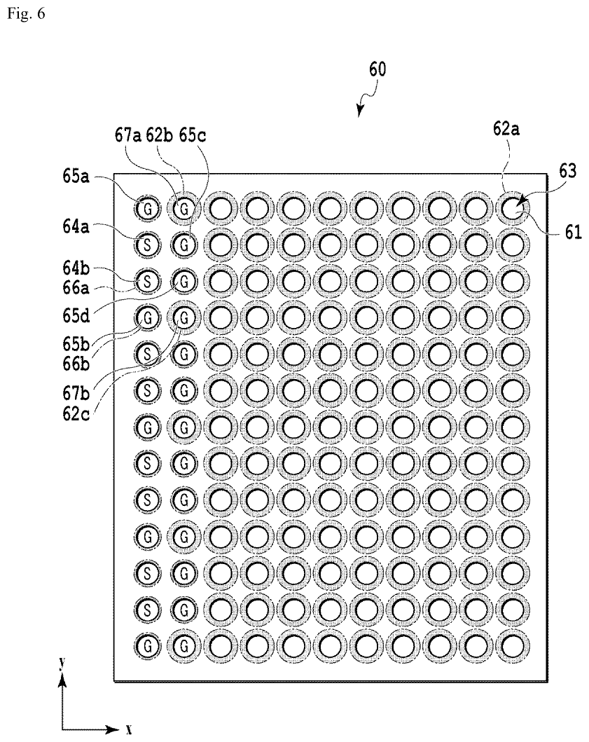

FIG. 6 is a diagram showing an electronic component package having a BGA pad of Example 1 of the present invention. FIG. 6 shows the suppression width of the solder resist or ceramic coat of each BGA pad of Example 1, as in FIG. 5. In the electronic component shown in FIG. 6, circular BGA pads 61 are disposed at predetermined pitches in the x-y direction in a lattice pattern in the x-y plane on one surface 60 of a package made of resin such as glass epoxy or ceramic. Each BGA pad is formed of a metal such as aluminum or copper. It is desirable that the BGA pad plated with gold, silver, palladium, or the like to enable soldering.

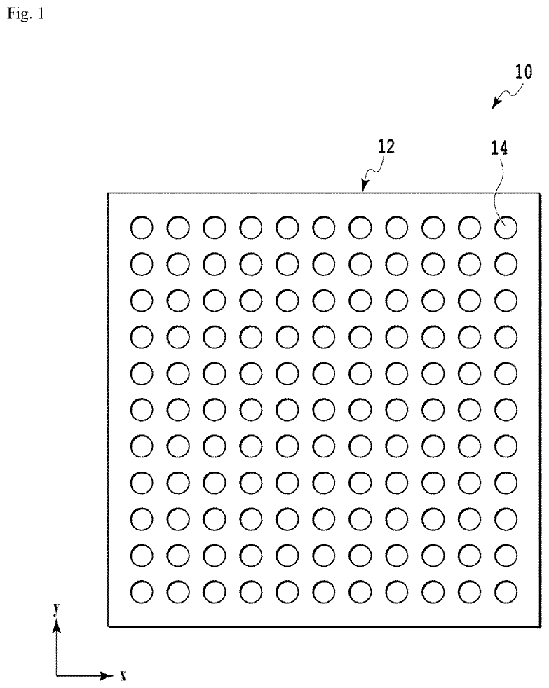

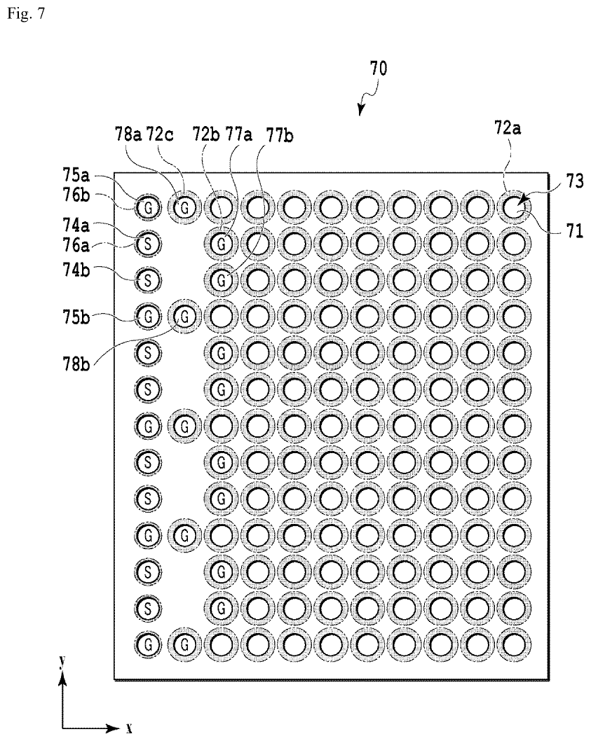

In the drawing, signal electrode BGA pads S for inputting or outputting high-speed electric signals are shown by pads having characters S in the pad opening. Similarly, a ground electrode BGA pad G is shown by a pad having a character G in the pad opening. The signal electrode BGA pad S and the ground electrode BGA pad G are disposed close to one side of one surface 60 of the electronic component package. In this example, the signal electrode BGA pads S are disposed in the first row of the BGA pads from the left, which constitute one side of the outermost periphery of the pad. The difference from the related art shown in FIG. 1 is that a suppression width 66a of signal electrode BGA pads S 64a and 64b and a suppression width 66b of solder resist or ceramic coat of ground electrode BGA pads G 65a to 65d adjacent to signal electrode BGA pads S 64a and 64bs in the x-direction and y-direction (hereinafter, the suppression width of the solder resist or ceramic coat will be simply referred to as the “suppression width”) is smaller than the suppression width 62a of the other BGA pad 61. In FIG. 6, for convenience of explanation, only those forming a pair of differential pairs among the signal electrode BGA pads S and the ground electrode BGA pads G are represented by reference numerals. In the following description, those forming a pair of the differential pairs is focus on, but the BGA pads forming the other three pairs of the differential pairs have the same configuration. In addition, only one of the other BGA pads 61 is denoted by reference numeral, representatively. In addition, only a part of each type of pad is denoted by reference numerals as to the suppression width of each pad. (The same also applies to FIGS. 7 to 9).

In FIG. 6, the size of the suppression widths 62b and 62c of the ground electrode BGA pads G 67a and 67b, which are obliquely adjacent to the signal electrode BGA pads S 64a and 64b, are the same as the size of the suppression width 62a of the other BGA pads 61. However, the width suppression width of the ground electrode BGA pads G 67a and 67b may be formed to be small in the same way as the ground electrode BGA pads 65a to 65d. However, as will be described later, since the strength of the pad is reduced when the pad suppression width is reduced, it is desirable that the pad for reducing the suppression width be as few pad as possible. Therefore, in this Example 1, the suppression width of only the ground electrode BGA pads G 65a to 65d adjacent in the x-direction and the y-direction, which are the ground electrode BGA pads closest to the signal electrode BGA pads S 64a and 64b, is formed to be small. The ground electrode BGA pads G 67a and 67b, which are obliquely adjacent to signal electrode BGA pads S 64a and 64b, may be pads other than the ground electrode pads.

In an optical transceiver for coherent optical communication, generally, in the case of differential transmission, a total of eight pairs of signal terminals of four pairs of transmission and four pairs of reception are used for a differential signal pair. As described above, these signal terminals are formed close to one side of the component. In FIG. 6, the terminals of the pair of differential signal pairs are made up of two adjacent signal electrode BGA pads S 64a and 64b and six ground electrode BGA pads G 65a to 65d, 67a, and 67b adjacent to the signal electrode BGA pad S. In FIG. 6, the transmission path BGA pads of a total of four pairs of differential signal pairs are formed at one end of the component.

Also in the electronic component package of this example, the BGA pads are disposed at a predetermined pitch in the x-y direction in the x-y plane, as in the related art. In the BGA shown in FIG. 1, the diameters of the respective BGA pads are the same, but in this example, the signal electrode BGA pads S 64a and 64b, the ground electrode BGA pads G 65c and 65d adjacent to the signal electrode BGA pads S in the x-direction, and ground electrode BGA pads G 65a and 65b adjacent to the signal electrodes in the y-direction have a pad diameter B smaller than a pad diameter B of other BGA pads 61 and the ground electrode BGA pads G 67a and 67b. The diameters A of the pad openings 64 of the signal electrode BGA pads S 64a and 64b, the ground electrode BGA pads G 65a to 65d, 67a and 67b, and the other BGA pads 61 are all set to be the same.

As described above, when a high-frequency signal is transmitted from the BGA pad by using the inner layer wiring such as a via formed in the substrate forming one surface of an electronic component package made of resin or ceramic, it is necessary to adjust and match the characteristic impedance of the transmission path formed by the inner layer wiring. The characteristic impedance of the transmission path can be adjusted by adjusting the interval between a signal electrode through which a high-frequency signal propagates and a ground electrode for making a return current flow. As described above, in order to secure the solder connection strength, the BGA pad needs to have a predetermined size or more, because the pad opening defining the area of the solder bump on the BGA pad needs to have a predetermined size or more. Therefore, even when the pitch of the BGA pads is made small for the purpose of miniaturizing the electronic component, it is not desirable that the size of the BGA pads be made smaller than a predetermined size. Due to such a restriction, when the BGA is miniaturized with the same number of BGA pads provided, since the gap between the BGA pads becomes narrow, there is a problem that the characteristic impedance becomes lower than an ideal value.

In Example 1, the suppression width of the signal electrode BGA pad S, which requires adjustment of characteristic impedance, and the ground electrode BGA pad G adjacent thereto is made smaller than the suppression width of other BGA pads. Thus, the size of the pad can be reduced, while maintaining the diameter of the opening pad to the same size. As a result, the gap D between the signal electrode BGA pad S and the ground electrode BGA pad adjacent thereto is made larger than the other while making the pitch C of the BGA pad and the opening pad diameter A equal to each other, and the deterioration of the characteristic impedance is prevented.

When the electronic component package is formed of ceramic, the suppression width of the ceramic coat is required to be 75 μm, for example, to ensure the strength of the BGA pad. In this example, for example, it is assumed that the suppression width of the signal electrode BGA pad and the ground electrode BGA pad adjacent thereto is set to 45 μm. Thus, the gap between the signal electrode and the adjacent ground electrode can be made larger by 30 μm×2 than that of the related art without impairing the strength of the other BGA pads.

As described above, in the electronic component package of Example 1, the characteristic impedance of the transmission path formed by the signal electrode and the ground electrode is prevented from decreasing, and the operating frequency of the electronic component can be widened.

In order to reduce the size, while providing all electronic components and terminals necessary for the operation of an optical transceiver used in an optical communication system, it is necessary to dispose the pitches of the BGA pads densely. The pitch between BGA pads is starting to be used from 0.5 mm interval to 0.4 mm interval, 0.3 mm interval, etc., and the gap between the signal electrode and the adjacent ground electrode tends to become narrower. Among these, in the electronic component package of Example 1, the distance between the signal electrode and the ground electrode adjacent thereto in the x-y direction can be made larger than that of the related art.

### Example 2

FIG. 7 is a diagram showing an electronic component package having a BGA pad of Example 2 of the present invention. FIG. 7 shows the suppression width of the BGA pad of Example 2, as in FIG. 5. In the electronic component shown in FIG. 7, circular BGA pads 71 are disposed at predetermined pitches in the x-y direction in a lattice pattern on an x-y plane which is one surface 70 of an electronic component package formed of a resin such as glass epoxy or ceramic. Each BGA pad is formed of a metal such as aluminum or copper. It is desirable that the BGA pad plated with gold, silver, palladium or the like to enable soldering.

Also in FIG. 7, the signal electrode BGA pads S and the ground electrode BGA pads G are shown in the same manner as in FIG. 6. The point different from the general electronic component package of the related art shown in FIG. 1 is that the suppression width 76a of the signal electrode BGA pads S 74a and 74b and the suppression width 76b of the ground electrode BGA pads S 75a and 75b adjacent to the signal electrode BGA pad S are smaller than the suppression width 72a of the other BGA pads 71. The second point is that the BGA pads adjacent to the signal electrode BGA pads S 74a and 74b in the x-direction are deleted, and the ground electrode BGA pads in the x-direction of the signal electrode BGA pads S 74a and 74b are made to be the BGA pads 77a and 77b adjacent to the deleted BGA pads in the x-direction. Thus, the interval between the signal electrode BGA pad S and the ground electrode BGA pads G 77a and 77b adjacent to the signal electrode BGA pad S in the x-direction is larger than the interval between the other BGA pads 71. That is, in Example 2, the interval between the signal electrode BGA pads S 74a and 74b and the ground electrode BGA pads 76a and 76b is larger than the interval between the other BGA pads which is the interval between the BGA pad S and the deleted BGA pad adjacent thereto. Also in FIG. 7, BGA pad terminals for transmission paths of four pairs of differential signal pairs are formed close to one side of the electronic component.

In the electronic component package of this Example 2, the BGA pads are disposed at a predetermined pitch in the x-y direction in a lattice pattern in the x-y plane, except for the interval between the signal electrode BGA pads S 74a, 74b, and the ground electrode BGA pads G 76a, 76b neighboring in the x-direction of the signal electrode BGA pad S. In the electronic component package of this Example 2, the pad diameter B of the signal electrode BGA pads S 74a, 74b, and the ground electrodes G 75a, 75b adjacent to the signal electrode BGA pad S in the y-direction, is smaller than the pad diameters of the other BGA pads 71, 77a, 77b, 78a, and 78b. In this Example 2, the ground electrodes G 75a and 75b which are closest to the signal electrode BGA pad S are only in the y-direction, and the BGA pads which are adjacent in the x-direction are deleted. Also in Example 2, the diameters A of the pad openings 73 of all the BGA pads are set to be the same. In Example 2, in order to reduce the number of pads for reducing the suppression width like Example 1, the suppression width 76b is made small only for the pads 75a and 75b adjacent in the y-direction closest to each other, and the suppression width 72c of the ground electrode pads 78a and 78b adjacent in the oblique direction is made the same as the suppression width 72b of the other BGA pad 71.

In Example 2, the ground electrode BGA pads neighboring to the signal electrode BGA pads S 74a and 74b in the x-direction are allocated to the BGA pads 77a and 77b adjacent to the deleted BGA pads in the x-direction. Therefore, an interval between the signal electrode BGA pads S 74a, 74b, and the ground electrode BGA pads G 76a, 76b neighboring to the signal electrode BGA pad S in the x-direction is larger than an interval between the signal electrode BGA pad S and the deleted BGA pad adjacent to the signal electrode BGA pad S in the x-direction, that is, the interval between the other BGA pads. The suppression width 72b of the ground electrode BGA pads 77a and 77b adjacent to the signal electrode pad in the x-direction is made equal to the suppression width 72a of the other pads, but it may be made narrower similarly to the ground electrode pads 75a and 75b. Further, the ground electrode BGA pads G neighboring to the signal electrode BGA pads S 74a and 74b in the x-direction may be the third and succeeding BGA pads adjacent to each other in the x-direction. As described above, in the case where a high-frequency signal is transmitted from the BGA pad by using the inner layer wiring such as the via formed in the substrate made of resin or ceramic, it is necessary to adjust and match the characteristic impedance of the transmission path formed by the inner layer wiring.

The characteristic impedance of the transmission path can be adjusted by adjusting the interval between the signal electrode through which a high-frequency signal propagates and a ground electrode for making a return current flow. As described above, in order to ensure solder connection strength, it is necessary to make the pad opening for defining the area of the solder bump larger than a predetermined size. Therefore, even when the interval between the BGA pads is reduced for downsizing the electronic component, it is not desirable that the size of the BGA pads is smaller than a predetermined size. Due to such a restriction, when the BGA is miniaturized with the same number of BGA pads provided, since the interval between the BGA pads becomes narrow, there is a problem that the characteristic impedance becomes lower than an ideal value.

In Example 2, the suppression widths of the signal electrode BGA pad S requiring adjustment of the characteristic impedance and the ground electrode BGA pad G adjacent thereto in the y-direction are made smaller than the suppression width of the other BGA pads. Thus, the interval between the signal electrode BGA pad S and the ground electrode BGA pad G adjacent thereto in the y-direction can be made large. Further, the signal electrode BGA pad S and the BGA pad adjacent to the BGA pad S in the x-direction are deleted, and the ground electrode BGA pad G (76) neighboring in the x-direction is disposed on the pad adjacent to the deleted pad in the same x-direction. Therefore, the interval between the signal electrode BGA pad S and the ground electrode BGA pad G neighboring to the BGA pad S in the x-direction can be made large. Therefore, the characteristic impedance of the transmission path configured in this way is prevented from being lowered, and the operating frequency of the electronic component is widened.

In order to reduce the size while providing all electronic components and terminals necessary for the operation of an optical transceiver used in an optical communication system, it is necessary to dispose the pitches of the BGA pads densely. The pitch between BGA pads is starting to be used from 0.5 mm interval to 0.4 mm interval, 0.3 mm interval, etc., and the gap between the signal electrode and the adjacent ground electrode tends to become narrower. In the BGA of Example 2, the gap between the ground electrode neighboring to the signal electrode in the x-direction and the ground electrode adjacent to the signal electrode in the y-direction can be made larger than that of the related art.

### Example 3

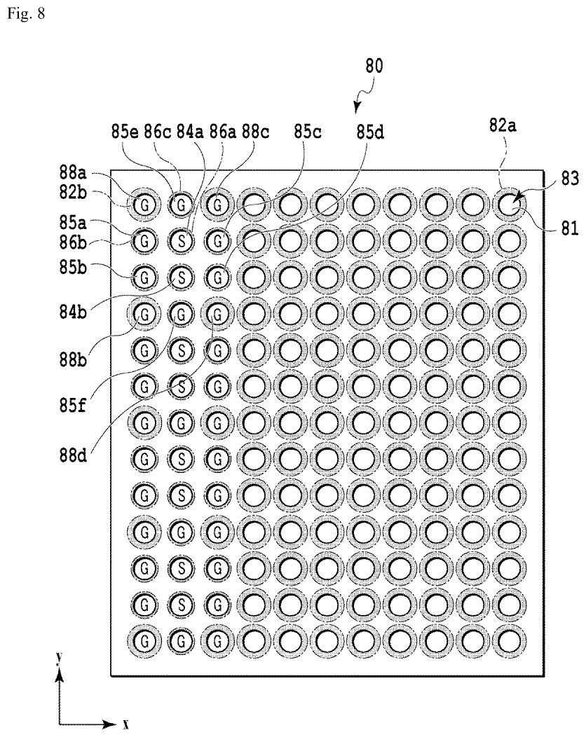

FIG. 8 is a diagram showing an electronic component package having a BGA pad of Example 3 of the present invention. In FIG. 8, the suppression width of the solder resist or ceramic coat of the BGA pad of Example 3 is shown, as in FIG. 5. Also in FIG. 8, the signal electrode BGA pads S and the ground electrode BGA pads G are shown in the same manner as in FIG. 6. In the BGA pad of Example 3, as in Example 1, a suppression width 87a of signal electrode BGA pads S 84a and 84b, and a suppression widths 86b and 86c of ground electrode BGA pads G 85a to 85d adjacent to the signal electrode BGA pad S in the x-direction and ground electrode BGA pads G 85e and 85f adjacent in the y-direction are smaller than the suppression width 82a of other BGA pad 81.

In Example 3, as shown in FIG. 8, a pair of operating signal terminals are made up of two adjacent signal electrode BGA pads S 84a and 84b for the differential signal pair, six ground electrode BGA pads G 85a to 85f adjacent to the signal electrode BGA pad S in the x, y-directions, and four ground electrode BGA pads G 88a to 88d obliquely adjacent to the signal electrode BGA pads S 84a and 84b, and a total of four pairs of transmission path BGA pad of differential signal pairs are formed. In this Example 3, unlike Example 1, signal electrode BGA pads S 84a and 84b for inputting or outputting electric signals are positioned in the second row of BGA pads from the left.

In the BGA pad row of the first row from the left, pads 88a and 88b having the same suppression width 82b as the suppression width 82a of the other pads are present, unlike Example 1. In the electronic component package of this example, the pad diameters of the signal electrode BGA pads S 84a and 84b and the ground electrode BGA pads G 85a to 85f are smaller than the pad diameters of the other BGA pads 81, similarly to Example 1. The diameters A of the pad openings 83 of all the BGA pads are set to be the same.

Since the suppression width 86a of the solder resist or ceramic coat of the signal electrode BGA pads S 84a and 84b and the suppression widths 86b and 86c of the ground electrode BGA pads G 85a to 85f adjacent thereto in the x-y direction are smaller than the suppression width 82a of the other BGA pads 81 and the suppression width 82b of the ground electrode BGA pads G 88a to 88d, its strength is lower than that of other BGA pads. When the strength of the BGA pad disposed at one end of the BGA pads disposed at a predetermined pitch in the x-y direction in the x-y plane is weaker than that of the other BGA pads, the BGA pad disposed at one end is easily broken by stress due to thermal shrinkage or pressing applied at the time of operation of the electronic component.

Therefore, in Example 3, signal electrode BGA pads S 84a and 84b are disposed in the second row of BGA pad rows from the left. In the BGA pad rows of the first row and the third row from the left, there are ground electrode BGA pads G 85a to 85d adjacent to the signal electrode BGA pads S 84a and 84b in the x-direction, and ground electrode BGA pads G 88a to 88d adjacent in the x-direction to ground electrode BGA pads G 85e and 85f adjacent to the signal electrode BGA pad S in the y-direction. Since the suppression widths 82b and 82c of the solder resist or ceramic coat of the ground electrode BGA pads G 88a to 88d have the same normal size as the suppression width 82a of the other BGA pads 81, the strength of the pad is not lowered. The ground electrode BGA pads 88a to 88d may be pads other than the ground electrode BGA pads.

Thus, in this Example 3, the BGA pads 88a and 88b whose strength is not lowered are disposed in the first row of the BGA pad rows from the left side of one end side of the electronic component. The BGA pads 88a and 88b can protect the signal electrode BGA pads S 84a and 84b whose strength is lowered and the ground electrode BGA pads G 85a to 85f adjacent to them in the x-direction and the y-direction.

In the electronic component package of Example 3, in addition to making the gap between the signal electrode and the ground electrode adjacent thereto in the x-y direction larger than that of the conventional one, it is possible to reduce the possibility that the signal electrode BGA pad S and the ground electrode BGA pad G adjacent thereto in the x-y direction break by stress due to thermal contraction or pressure applied during operation.

### Example 4

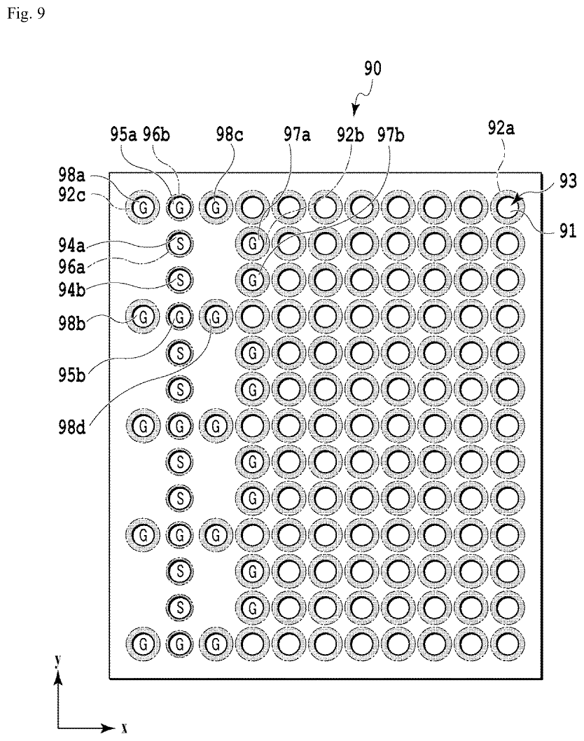

FIG. 9 is a diagram showing an electronic component package having a BGA pad according to Example 4 of the present invention. FIG. 9 shows the suppression width of the BGA pad in Example 4, as in FIG. 5. Also in FIG. 9, the signal electrode BGA pads S and the ground electrode BGA pads G are shown in the same manner as in FIG. 6. In the BGA pad of Example 4, as in Example 1, the suppression width 96a of the signal electrode BGA pads S 94a and 94b, and the suppression width 96b of the ground electrode BGA pads G 95a and 95b adjacent to the signal electrode BGA pad S in the y-direction are smaller than the suppression width 92a of the other BGA pads 91.

Similarly to Example 2, the BGA pads adjacent to the signal electrode BGA pads 94a and 94b in the x-direction are deleted. The ground electrode BGA pads corresponding to the x-direction of the signal electrode BGA pads S 94a and 94b are used as the BGA pads 97a and 97b at positions adjacent to the removed BGA pads in the same x-direction. As a result, the interval between the signal electrode BGA pads S 94a and 94b and the ground electrode BGA pads S 96a and 96b neighboring to the signal electrode BGA pads the x-direction is set to be larger than the interval between other BGA pads 91.

That is, in Example 4, the interval between the signal electrode BGA pads S 94a and 94b and the ground electrode BGA pads G 96a and 96b is larger than the interval between the electrodes of the other BGA pads which is the interval between the BGA pads S 94a and 94b and the deleted BGA pads adjacent thereto. In Example 4, the signal electrode BGA pads S 94a and 94b are positioned in the second row of BGA pads from the left, similarly to Example 3. Therefore, in Example 4, the BGA pads adjacent to the signal electrode BGA pads S 94a and 94b in the x-direction and to be deleted exist on the left and right sides in the x-direction of the signal electrode BGA pad S.

In Example 4, when the signal electrode BGA pads S 94a and 94b are positioned in the third row of BGA pads from the left, a ground electrode pad G neighboring to the signal electrode BGA pad S is disposed on the left side in the x-direction of the signal electrode BGA pads S 94a and 94b.

As shown in FIG. 9, the pair of differential signal terminals is constituted by two signal electrode BGA pads S 94a and 94b, two ground electrode BGA pads G 95a and 95b adjacent to BGA pad S in the y-direction, two ground electrode BGA pads G 97a and 97b neighboring to signal electrode BGA pad S in the x-direction, and ground electrode BGA pads G 98a to 98d adjacent to ground electrode BGA pads G 95a and 95b in the x-direction adjacent to signal electrode BGA pad S in the y-direction.

Also in this Example 4, as shown in FIG. 9, four pairs of transmission path GPA pads of differential signal pairs are formed.

Also in this Example 4, as in Example 2, the pad diameters of the signal electrode BGA pads S 94a and 94b and the ground electrode BGA pads G 95a and 95b adjacent to the signal electrode BGA pad S in the y-direction are smaller than those of the other BGA pad 91, the ground electrode BGA pads G 97a and 97b, and the ground electrode BGA pads G 98a to 98d. The diameters A of the pad openings 93 of all the BGA pads are set to be the same. In this Example 4, as in Example 2, the BGA pads are disposed at a predetermined pitch in the x-y direction within the x-y plane except for the interval between the signal electrode BGA pads S 94a and 94b and the ground electrode BGA pads G 97a and 97b adjacent to each other in the x-direction of the signal electrode BGA pad S.

In Example 4, as in Example 2, the suppression widths of the signal electrode BGA pads S requiring adjustment of the characteristic impedance and the ground electrode BGA pads G adjacent to the signal electrode BGA pads S in the y-direction are made smaller than the suppression widths of the other BGA pads. Thus, the gap between the signal electrode BGA pad S and the ground electrode BGA pad G adjacent thereto in the y-direction can be made large.

In Example 4, the BGA pads adjacent to the signal electrode BGA pads S 94a and 94b in the x-direction are deleted. The BGA pads 97a and 97b adjacent to the deleted BGA pads in the same x-direction are used as ground electrode BGA pads G neighboring to the signal electrode BGA pads S in the x-direction. Thus, the interval between the signal electrode BGA pad S and the ground electrode BGA pad G neighboring thereto in the x-direction is larger than the interval between the other BGA pads. As a result, the characteristic impedance of the transmission path constituted of these components is prevented from being lowered, and the operating frequency of the electronic component is widened.

Further, in this Example 4, the signal electrode BGA pads S 94a and 94b are disposed in the second row of the BGA pad row from the left. The BGA pads adjacent to the signal electrode BGA pads S 94a and S94b of the BGA pad row of the first row from the left are deleted. In the BGA terminal row of the first row from the left, ground electrode BGA pads 98a and 98b adjacent in the x-direction to ground electrode BGA pads G 95a and 95b adjacent in the y-direction to signal electrode BGA pads S 94a and 94b exist. The BGA pads 98a to 98d may be pads other than ground electrode BGA pads.

Since the suppression width 92c of the BGA pads 98a to 98d has the same normal size as the suppression width 92a of the other BGA pads 91, the strength of the BGA pads is not lowered. Therefore, in Example 4, as in Example 3, it is possible to reduce possibility that signal electrode BGA pads S94a and 94b and ground electrode BGA pads 95a and 95b adjacent thereto in the y-direction break by stress caused by heat shrinkage or pressure applied during operation.

### Effects of Invention

As described above, according to the present invention, in an electronic component such as an IC or an optical transceiver having BGA pads, by generating a structure in which the gap between the signal electrode BGA pads and the signal electrode BGA pads that require adjustment of characteristic impedance can be made larger than the gap between BGA pads disposed at a predetermined pitch, the characteristic impedance of the BGA connection part can be maintained at an appropriate value without decreasing. By realizing an IC and an optical transceiver with impedance matching by the present invention, it is possible to provide a compact, large-capacity, and highly functional optical communication system.

### Industrial Applicability

The present invention can be generally used in optical communication systems. In particular, the present invention relates to an electronic component package, such as an optical transceiver having a BGA pad, for use in an optical communication system.

1. An electronic component package in which pads are disposed on an x-y plane in a lattice pattern in an x-direction and a y-direction orthogonal to the x-direction at a predetermined pitch,
wherein a suppression width of a solder resist or a ceramic coat and a size of a pad of a signal electrode pad disposed on one side of an outermost periphery and configured to input or output a high-frequency signal, and a ground electrode pad adjacent to the signal electrode pad in the x-direction and the y-direction are smaller than a suppression width of the solder resist or the ceramic coat of other pads and a size of a pad.

2. An electronic component package in which pads are disposed on an x-y plane in a lattice pattern in an x-direction and a y-direction orthogonal to the x-direction at a predetermined pitch,
wherein a suppression width of a solder resist or a ceramic coat and a size of a pad of a signal electrode pad disposed in a second row on one side of the outermost periphery and configured to input or output a high-frequency signal, and a ground electrode pad adjacent to the signal electrode pad in a x-direction and a y-direction are smaller than a suppression width of the solder resist or the ceramic coat of other pads and a size of a pad.

3. The electronic component package according to claim 1,
wherein the suppression width of the solder resist or ceramic coat of the pad adjacent in the x-direction to the ground electrode pad adjacent to the signal electrode pad in the y-direction and the size of the pad are the same as those of the other BGA.

4. An electronic component package in which pads are disposed at predetermined pitches in a lattice pattern in an x-direction of an x-y plane and a y-direction orthogonal to the x-direction, the electronic component package comprising:
a signal electrode pad disposed on one side of an outer periphery of an electronic component and configured to input or output a high-frequency signal; and a ground electrode pad neighboring to the signal electrode pad in the x-direction,
wherein the pad adjacent to the signal electrode pad in the x-direction is deleted, and an interval between the signal electrode pad and the ground electrode pad neighboring to the signal electrode pad in the x-direction is larger than an interval between other pads.
